(19) United States
(12) Patent Application Publication
(10) Pub. No.: US 2015/0359088 A1
(43) Pub. Date: Dec. 10, 2015

(54) ELECTRONIC DEVICE AND METHOD FOR PRODUCING SAME

(71) Applicant: SHARP KABUSHIKI KAISHA, Osaka (JP)

(72) Inventors: Masahiro KONISHI, Osaka-shi (JP); Yuhsuke FUJITA, Osaka-shi (JP); Ippei YAMAGUCHI, Osaka-shi (JP); Takashi NAKANISHI, Osaka-shi (JP); Hiroyuki NOKUBO, Osaka-shi (JP)

(73) Assignee: Sharp Kabushiki Kaisha, Osaka (JP)

(21) Appl. No.: 14/759,286

(22) PCT Filed: Dec. 17, 2013
(86) PCT No.: PCT/JP2013/083778

§ 371 Date: Jul. 6, 2015

(30) Foreign Application Priority Data
Jan. 24, 2013 (JP) 2013-011396

(51) Int. Cl. H05K 1/02; H05K 1/18; H01L 33/64; B23K 1/00; H01L 33/62; H05K 1/05; H05K 3/34

(52) U.S. Cl. CPC H05K 1/0295; H05K 1/053; H05K 1/181; H05K 3/341; B23K 1/0016; H01L 33/62; H01L 33/641; H05K 2201/10106; H05K 2201/10189; H05K 2201/10287

(57) ABSTRACT

A first land portion (2f) or a second land portion (2s) is formed on a board (1), and a first connector (20b) or a second connector (20s) is electrically connected while the first connector (20b) or the second connector (20s) is placed on the first land portion (2f) or the second land portion (2s).

### TECHNICAL FIELD

The present invention relates to an electronic device including an electronic circuit board on which an electron element is arranged and a method for producing the same.

### BACKGROUND ART

A light-emitting device including an electronic circuit board with an insulating layer on a metal substrate, a thermoelectric conversion device including one pair of metal substrates joined to two ends of a thermoelectric element with electrode members therebetween, or the like has been known as an example of an electronic device including an electronic circuit board on which a light-emitting element, such as a light emitting diode (LED), or an electron element, such as a thermoelectric element, is arranged. For example, PTL 1 discloses a technique for forming an insulating coating by applying a ceramic paint to a base, such as an aluminum plate.

### CITATION LIST

### Patent Literature

PTL 1: Japanese Unexamined Patent Application Publication No. 59-149958 (laid open on Aug. 28, 1984)

### SUMMARY OF INVENTION

### Technical Problem

The above-described conventional electronic device adopts a metal substrate. To form an electronic circuit wiring pattern on a metal substrate, an insulating layer needs to be formed on the metal substrate, as in the technique disclosed in PTL 1 above.

The use of an electronic circuit board, in which an insulating layer is formed on a metal substrate, however, suffers from a problem in the prior art. The problem is the difficulty of electrically connecting an electrode at a portion of a wiring pattern formed on an arrangement surface on which an electron element is to be arranged (for example, a light source placement surface of a light bulb, a light source placement surface of a spotlight, or a thermoelectric element arrangement surface of a thermoelectric conversion device) to a conductor for connection to a piece of external wiring (or an external device).

For example, a conventional light source placement surface is typically composed of a heat sink (for example, a metallic electronic circuit board) and is excellent in heat dissipation in general. When a conductor is to be directly soldered to an electrode at a portion of a wiring pattern, solder is locally heated. At this time, soldering is difficult due to excessive heat dissipation.

To directly solder a conductor to an electrode at a portion of a wiring pattern, it is common to perform soldering while a light-emitting device is fixed to a heat sink. This is because the position of an end portion of a conductor relative to a connector is changeable without the fixation, and soldering of a connector or a bare conductor is difficult.

Note that PTL 1 above has no reference to how to electrically connect an electrode at a portion of a wiring pattern to a conductor.

The present invention has been made in view of the above-described problem and has as an object to provide an electronic device or the like that allows easy electrical connection of a portion of a wiring pattern on a substrate to an outside conductor.

### Solution to Problem

In order to solve the above-described problem, an electronic device according to one aspect of the present invention includes an electronic circuit board which includes a metallic substrate and an insulating layer formed on the metallic substrate, an electronic circuit wiring pattern which is arranged on the insulating layer and is connected to an electron element, and a connector which is loaded on the electronic circuit board and is configured to electrically connect the wiring pattern to an outside conductor.

### Advantageous Effect of Invention

The one aspect of the present invention has the effect of allowing easy electrical connection of a portion of a wiring pattern on a board to an outside conductor.

Additional objects, features, and strengths of the present invention will be made sufficiently clear by the description below. Further, advantages of the present invention will be evident from the following explanation taken in conjunction with the accompanying drawings.

### BRIEF DESCRIPTION OF DRAWINGS

FIG. 1 is configurational views showing the overall configuration of a light-emitting device according to a first embodiment of the present invention. FIG. 1(a) is a top view of the light-emitting device, FIG. 1(b) is a side view of the light-emitting device, FIG. 1(c) shows a form in which a conductor (connection cable) is connected to a first connector, and FIG. 1(d) shows a form in which the conductor (connection cable) is connected to a second connector.

FIG. 2 is a top view of a light-emitting device including the second connector as a modification of the light-emitting device of the first embodiment.

FIG. 3 is structural views showing the structures of electronic circuit boards of light-emitting devices according to embodiments of the present invention. FIG. 3(a) shows an electronic circuit board of the light-emitting device according to the first embodiment of the present invention, and FIG. 3(b) shows an electronic circuit board of a light-emitting device according to a second embodiment of the present invention.

FIG. 4 is views showing modifications of the light-emitting device according to the first embodiment of the present invention. FIG. 4(a) relates to the light-emitting device according to the first embodiment of the present invention and shows an example of an electronic circuit board with a Zener diode placed through reflowing, and FIG. 4(b) shows an example of an electronic circuit board with a Zener diode electrically connected through die bonding and wire bonding.

FIG. 5 is step views showing steps in a method for producing a light-emitting device according to a third embodiment of the present invention. FIG. 5(a) shows a state after a solder placement step of placing (printing) a solder portion on a land portion, FIG. 5(b) shows a state after a connector is placed (mounted) on the solder portion, FIG. 5(c) shows a step of heating the light-emitting device in a reflow furnace, and FIG. 5(d) shows a state when the light-emitting device is completed by a connector connection step shown in FIGS. 5(b) and 5(c).

FIG. 6 is a view showing a state in which a light-emitting device according to a fourth embodiment of the present invention that is also the light-emitting device according to the first embodiment is fixed with screws to a heat sink.

### DESCRIPTION OF EMBODIMENTS

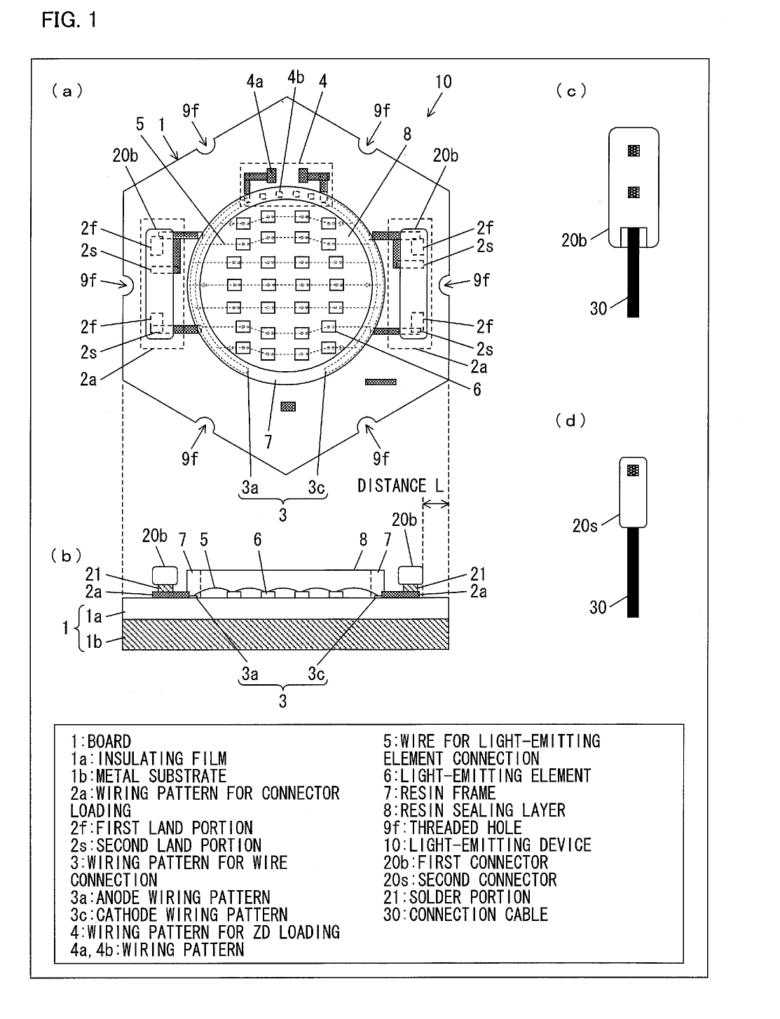

Embodiments of the present invention will be described with reference to FIGS. 1 to 6 as follows. A description of a component other than components to be described in a specific one of the embodiments below may be omitted as needed. If a description of the component is given in a different embodiment, the specific embodiment has a component equal to the component. For the purpose of illustration, a member identical in function to members illustrated in the embodiments is denoted by an identical reference character, and a description of the member will be appropriately omitted. The shape and dimensions, such as length, size, and width, of each component illustrated in the drawings are not a reflection of the actual shape and dimensions and are obtained by appropriately changing the actual shape and dimensions for purposes of clarity and brevity.

The embodiments to be described below will be described in the context of a light-emitting device, including an electronic circuit board with an insulating layer on a metal substrate as an example of an electronic device according to an embodiment of the present invention. The present invention, however, is not limited to this. For example, the present invention can also be applied to a thermoelectric conversion device or the like including one pair of metal substrates joined to two ends of a thermoelectric element with an electrode member therebetween.

### First Embodiment

FIG. 1(a) is a top view showing one configuration example of a light-emitting device (electronic device) 10 according to the present embodiment, and FIG. 1(b) is a side view of the light-emitting device 10. FIG. 1(c) shows a form in which a connection cable (outside conductor) 30 is connected to a first connector 20b. FIG. 1(d) shows a form in which the connection cable (outside conductor) 30 is connected to a second connector 20s.

As shown in FIGS. 1(a) and 1(b), the light-emitting device 10 includes a board (electronic circuit board) 1, wiring patterns 2a for connector loading, a wiring pattern 3 for wire connection, a wiring pattern 4 for ZD loading, wires (bonding wires) 5 for light-emitting element connection, light-emitting elements (electron elements) 6, a resin frame 7, a resin sealing layer 8, the first connectors 20b, and solder portions (solder) 21.

### (Substrate 1)

As shown in FIG. 1(b), the board 1 includes an insulating film (insulating layer) 1a and a metal substrate (metallic substrate) 1b. The insulating film 1a is a film which is formed on one side (hereinafter referred to as a surface) of the metal substrate 1b by printing and has electrical insulation, high light reflectivity, and high thermal conductivity. The material for the insulating film 1a of the present embodiment is not particularly limited as long as the material is a material which has electrical insulation and is high in light reflectivity and thermal conductivity. For example, a zirconia-based ceramic can be used. With this configuration, heat generated in each light-emitting element 6 can be dissipated to the metal substrate 1b via the insulating film 1a. This allows achievement of high thermal conductivity. Light leaking from the light-emitting element 6 in a substrate surface direction of the metal substrate 1b can be reflected by the insulating film 1a. This allows achievement of high thermal conductivity and high light reflectivity. If the metal substrate 1b is made of aluminum having a low melting point, use of a zirconia-based ceramic which is sintered at a sintering temperature lower than the melting point of aluminum makes it possible to sinter ceramic onto the surface of the metal substrate 1b while maintaining the shape of the metal substrate 1b.

The metal substrate 1b is a thermally-conductive substrate high in thermal conductivity. The material for the metal substrate 1b is not particularly limited as long as the material is a material high in thermal conductivity. For example, a substrate made of a metal, such as aluminum or copper, can be used. An aluminum substrate is used in the present embodiment because aluminum is inexpensive, is easy to process, and is resistant to atmospheric humidity. Note that the coefficient of thermal conductivity of a metallic substrate is preferably not less than 200 [W/m·K]. The coefficient of thermal conductivity of an aluminum substrate is 230 [W/m·K]. If copper (having a coefficient of thermal conductivity of 398 [W/m·K]) is used as the material for the metal substrate 1b, the coefficient of thermal conductivity of the metal substrate 1b is 398 [W/m·K].

The contour shape in the substrate surface direction of the board 1 is hexagonal in the present embodiment. The contour of the board 1, however, is not limited to this, and any closed figure shape can be adopted. The closed figure shape may be a shape of a closed figure, a periphery of which is composed only of straight lines or curved lines, or may be a shape of a closed figure shape, a periphery of which includes at least one straight portion and at least one curved portion. The closed figure shape is not limited to a convex figure shape and may be a concave figure shape. Examples of a convex polygonal shape composed only of straight lines include a triangular shape, a rectangular shape, a pentagonal shape, and an octagonal shape. Alternatively, any concave polygonal shape may be adopted. Examples of a closed figure shape composed only of a curved line include a circular shape and an elliptical shape. Alternatively, the closed figure shape may be a closed figure shape, such as a convex curved shape or a concave curved shape. Examples of a closed figure shape including at least one straight portion and at least one curved portion include a race track shape.

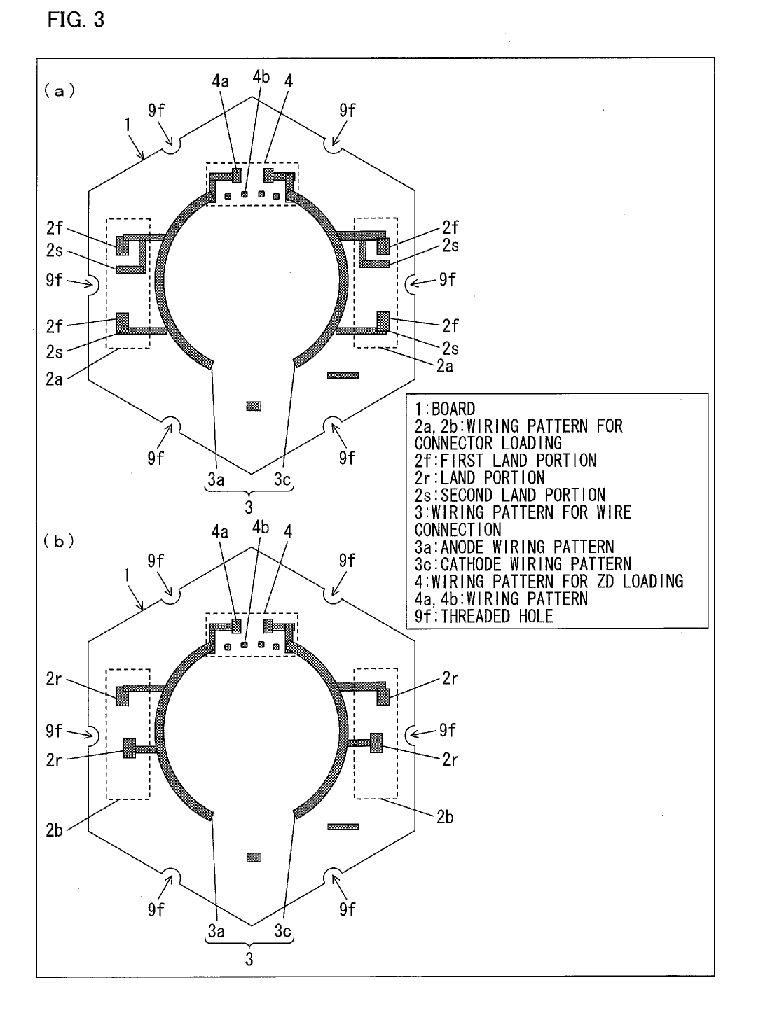

An electronic circuit wiring pattern which is connected to the light-emitting elements 6 is formed on a surface of the insulating film 1a. The wiring pattern mainly includes the wiring patterns 2a for connector loading, the wiring pattern 3 for wire connection, and the wiring pattern 4 for ZD loading. Note that the structure of the board 1 according to the present embodiment with the wiring patterns is shown in FIG. 3(a).

### (Wiring Pattern 2a for Connector Loading)

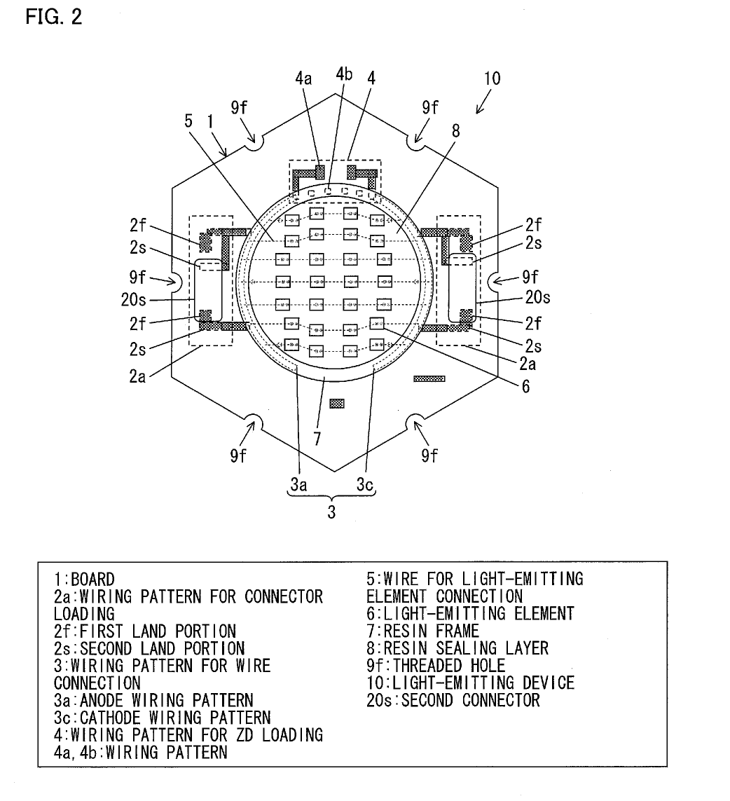

In each wiring pattern 2a for connector loading shown in FIGS. 1(a) and 2, first land portions 2f for placing the first connector 20b and second land portions 2s for placing the second connector 20s, both of which are to be described later, are formed. In the form shown in FIG. 1, each first connector 20b is electrically connected while being placed on the first land portions 2f. In contrast, in the form shown in FIG. 2, each second connector 20s is electrically connected while being placed on the second land portions 2s. In the form shown in FIG. 1, each first land portion 2f is electrically connected to the first connector 20b using the solder portion 21, as shown in, for example, FIGS. 1(a) and 1(b). Similarly, in the form shown in FIG. 2, each second land portion 2s is electrically connected to the second connector 20s using the solder portion 21.

In the case of a connector same in shape as and smaller in size than the connector in FIG. 1(c), the connector is electrically connected while being placed on the second land portion 2s on the upper side with respect to the sheet surface and the first land portion 2f on the lower side (in a region overlapping with the second land portion 2s).

Each wiring pattern 2a for connector loading is split into two wiring patterns. The wiring patterns are wiring patterns (hereinafter referred to as “upper-side wiring patterns”) which are connected to the respective upper sides with respect to the sheet surface of an anode wiring pattern 3a and a cathode wiring pattern 3c of the wiring pattern 3 for wire connection (to be described later) and wiring patterns (hereinafter referred to as “lower-side wiring patterns”) which are connected to the respective lower sides. In the present embodiment, each upper-side wiring pattern is further divided into two branches: a branch linked to the first land portion 2f for the first connector 20b and a branch linked to the second land portion 2s for the second connector 20s. With this configuration, each lower-side wiring pattern can be shared by the first connector 20b and the second connector 20s. For this reason, an area occupied by each wiring pattern 2a for connector loading of the board 1 can be made smaller than in a form with a total of four such land portions, one pair for each connector.

The above-described configuration improves the stability of positions of the first connector 20b and the second connector 20s (or connection positions of the connection cable 30) relative to the first land portions 2f and the second land portions 2s during heating in a reflow furnace in a connector connection step of a production method according to a third embodiment (to be described later).

### (Wiring Pattern 3 for Wire Connection)

The wiring pattern 3 for wire connection includes the anode wiring pattern 3a and the cathode wiring pattern 3c. The anode wiring pattern 3a is connected to anode-side terminals of the wires (bonding wires) 5 for light-emitting element connection, to which a plurality of light-emitting elements 6 (to be described later) (four in series and seven in parallel in the present embodiment) are connected in series while the cathode wiring pattern 3c is connected to cathode-side terminals of the wires 5 for light-emitting element connection, to which the plurality of light-emitting elements 6 are connected in series.

Although a curved shape has been illustrated as the shape of the wiring pattern 3 for wire connection of the present embodiment, the shape may be a linear shape, a step-like shape, or a ramiform shape. A linear or curved wiring pattern may be further formed between the anode wiring pattern 3a and the cathode wiring pattern 3c of the wiring pattern 3 for wire connection.

### (Wiring Pattern 4 for ZD Loading)

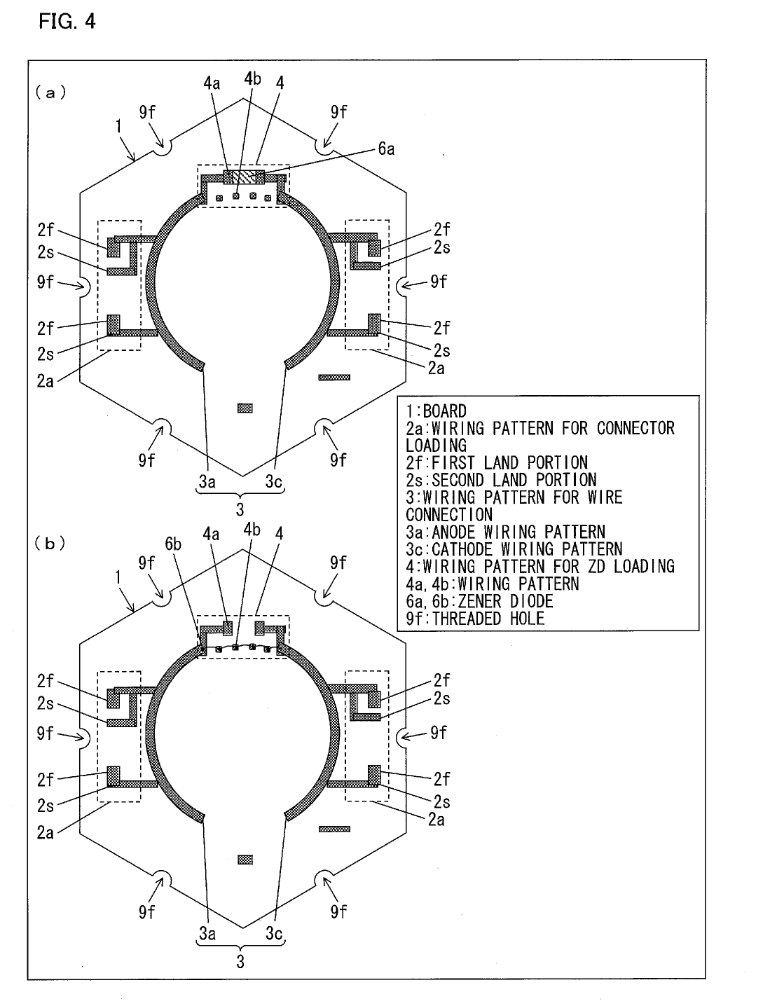

The wiring pattern 4 for ZD loading shown in FIGS. 3 and 4 includes a wiring pattern (a land portion for a protection element) 4a and a wiring pattern 4b. Note that ZD stands for Zener diode. The wiring pattern 4a is a wiring pattern for connecting a Zener diode (protection element) 6a through reflowing. For example, in the form shown in FIG. 4(a), the Zener diode 6a is reflowed while being placed on land portions facing each other of the wiring pattern 4a. Note that the Zener diode 6a [or a Zener diode (protection element) 6b (to be described later)] functions as a resistance element for protecting the light-emitting element 6 from an electrostatic withstand voltage. In contrast, the wiring pattern 4b is a wiring pattern for die-bonding at least one Zener diode 6b and electrically connecting the Zener diode 6b to a desired piece of wiring through wire bonding. For example, in the form shown in FIG. 4(b), five Zener diodes 6b in total are fixed (connected) with silver paste and are connected by a wire. If a Zener diode is loaded on the wiring pattern 4b, absorption of light from the light-emitting element 6 can be reduced by covering the Zener diode by the resin frame 7 (to be described later). Alternatively, the Zener diode may be concealed from the outside. As described above, a Zener diode which is connected in parallel to a circuit, in which a plurality of light-emitting elements 6 are series-connected (four in series and seven in parallel in the form shown in FIG. 1) may be further arranged as a resistance element for protecting the light-emitting elements 6 from the electrostatic withstand voltage on the surface of the insulating film 1a.

### (Light-Emitting Element 6)

The light-emitting element 6 is a semiconductor light-emitting element, such as a light emitting diode (LED). The present embodiment employs a blue light-emitting element which emits light in a blue region having an emission peak wavelength of about 450 nm. Note that the configuration of the light-emitting element 6 is not limited to this and that, for example, a light-emitting element which emits light in an ultraviolet (near-ultraviolet) region having an emission peak wavelength of 390 nm to 420 nm may be employed. Use of the above-described ultraviolet (near-ultraviolet) light-emitting element allows achievement of further improvement in luminous efficiency.

A plurality of light-emitting elements 6 (which are a total of 28 light-emitting elements 6 arranged four in series and seven in parallel in the present embodiment but may be a plurality of light-emitting elements 6 arranged in series) are arranged at prescribed positions which can achieve a prescribed light emission amount on the surface of the insulating film 1a. Electrical connection of the light-emitting element 6 (electrical connection to the anode wiring pattern 3a, the cathode wiring pattern 3c, and the like) is performed through wire bonding using the wire 5 for light-emitting element connection, as shown in FIG. 1(b). For example, a gold wire can be used as the wire 5 for light-emitting element connection. Wire bonding is a connection technique low in cost and high in flexibility. For this reason, the above-described configuration allows a reduction in expense and processing cost.

### (Resin Frame 7 and Resin Sealing Layer 8)

The resin frame 7 forms an annular (arc-like) light reflection resin frame which is made of an alumina filler-containing silicone resin. Note that the material for the resin frame 7 is not limited to this, and any material may be used as long as the material is an insulative resin having light reflection characteristics. The shape of the resin frame 7 is not limited to an annular shape (an arc-like shape), and a ring shape which has the shape of an arbitrary closed figure, such as a triangle, a rectangle, a polygon, or an elliptical shape, may be employed. The same applies to the shapes of the anode wiring pattern 3a, the cathode wiring pattern 3c, and the wiring pattern 4b.

The resin sealing layer 8 is a sealing resin layer made of a transparent resin. The resin sealing layer 8 is formed by filling a region surrounded by the resin frame 7 with the transparent resin and seals in the insulating film 1a, the light-emitting elements 6, the wires 5 for light-emitting element connection, and the like. Note that the resin sealing layer 8 may contain a phosphor. A phosphor which is excited by primary light emitted from the light-emitting element 6 and emits light having a wavelength longer than that of the primary light is used as the phosphor. The composition of the phosphor is not particularly limited, and an appropriate selection can be made in accordance with the chromaticity of a desired white color and the like. For example, a combination of a YAG yellow phosphor and a (Sr,Ca)AlSiN₃:Eu red phosphor, a combination of a YAG yellow phosphor and a CaAlSiN₃:Eu red phosphor, or the like can be used as a daylight combination or a warm white combination. A combination of a (Sr,Ca)AlSiN₃:Eu red phosphor and a Ca₃(Sc,Mg)₂Si₃O₁₂:Ce green phosphor, or the like can be used as a high color rendering combination. Any other combination of phosphors may be used, or a composition including only a YAG yellow phosphor may be used as a pseudo white one.

As described above, in the light-emitting device 10 of the present embodiment, the light-emitting elements 6, the first connectors 20b and the wiring patterns 2a for connector loading for connecting the light-emitting device 10 to a piece of external wiring (or an external device), the wires 5 for light-emitting element connection for connecting the light-emitting elements 6 to the anode wiring pattern 3a and the cathode wiring pattern 3c, a frame portion (the resin frame 7) which is formed so as to surround the region where the light-emitting elements 6 are arranged and is made of a light-reflective resin, and the resin sealing layer 8 that seals in members (a portion of the insulating film 1a, the light-emitting elements 6, the wires 5 for light-emitting element connection, and the like) arranged in the region surrounded by the frame portion are directly formed on the surface of the insulating film 1a.

(Threaded Hole 9f)

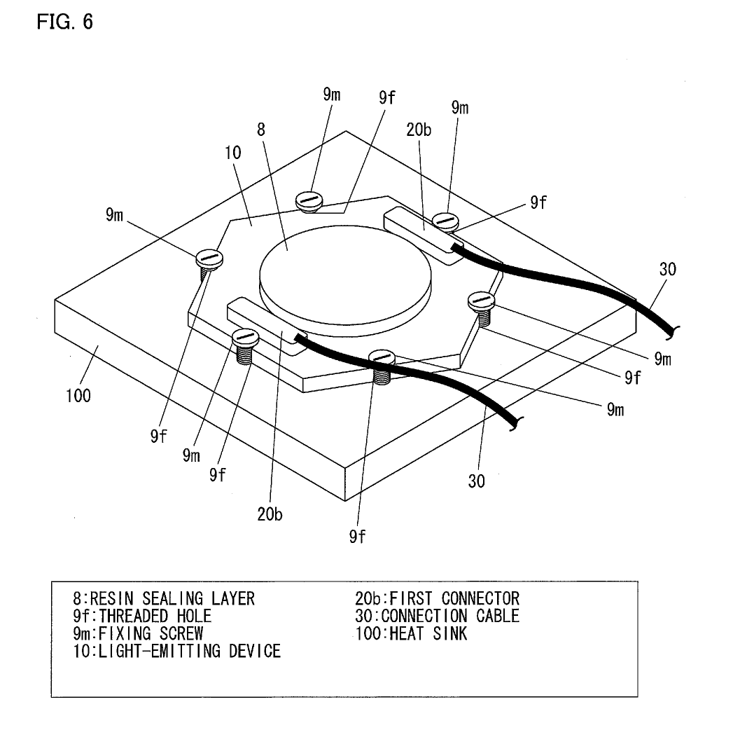

A threaded hole 9f shown in FIG. 1(a) is a threaded hole for fixing the light-emitting device 10 to a heat sink 100 (to be described later) using a fixing screw 9m (see FIG. 6).

(First Connector 20b and Second Connector 20s)

The first connector 20b shown in FIG. 1(c) is a connector which is loaded on the board 1 and is a connector for electrically connecting the wiring pattern 2a for connector loading to the connection cable 30 via the first land portions 2f shown in FIG. 1(a). The second connector 20s shown in FIG. 1(d) is a connector which is loaded on the board 1 and is a connector for electrically connecting the wiring pattern 2a for connector loading to the connection cable 30 via the second land portions 2s shown in FIG. 1(a). Note that, as shown in FIGS. 1(c) and 1(d), the size of the second connector 20s is smaller than that of the first connector 20b. As described above, in the light-emitting device 10 of the present embodiment, a plurality of connectors different in size can be properly used. As shown in FIG. 1(b), the first connector 20b is located at a distance L from an end of the board 1. To secure a dielectric voltage of 6 kV, the distance L is preferably not less than 6 mm. The distance from a surface of the board 1 to the top of the first connector 20b (or the second connector 20s) (a connector height) is preferably made as small as possible so as not to affect light emission from the light-emitting device 10.

### (Connection Cable 30)

The connection cable 30 is a connection cable for connecting the first connector 20b or the second connector 20s to a piece of external wiring (or an external device). In the present embodiment, each end portion of the connection cable 30 is not sheathed and is a bare conductor portion. Insertion of one end portion of the connection cable 30 into a connection cable slot of the first connector 20b (or the second connector 20s) allows electrical connection to the connector. This eliminates the need to disassemble a connector and connect an end portion of a connection cable to a conductor portion in the connector and allows improvement in the convenience of users. As a connector, a connection cable-compatible connector which is of the harness type and is detachable or a connection cable-compatible connector from which a lead wire is not detachable, is small, is low-profile, and is compatible to a stranded wire is preferable.

Although a form in which the first land portions 2f and the second land portions 2s (two sets of a total of three land portions) are formed for two types of connectors, the first connector 20b and the second connector 20s, has been described in the present embodiment, the number of types of connectors to be connected to the light-emitting device 10 and the number of land portions are not limited to this. For example, the number of types of connectors may be one or three or more, and the number of land portions on one of left and right sides may be one, two, or four or more. Note that since if the number of types of connectors and the number of land portions are too large, an area occupied by the wiring pattern 2a for connector loading with respect to the board 1 is too large, the numbers are preferably adjusted as needed.

As described above, in the light-emitting device 10, the first land portions 2f for placing the first connector 20b are formed in the wiring pattern 2a for connector loading, and the first connector 20b is electrically connected to the first land portions 2f with the first connector 20b placed on the first land portions 2f. For this reason, a user can electrically connect a portion of a wiring pattern to the connection cable 30 with ease just by fitting the connection cable 30 into the first connector 20b without directly soldering the portion of the wiring pattern and the connection cable 30. This eliminates the conventional need to fix the light-emitting device 10 to the heat sink at the time of soldering and allows a user to electrically connect, via the first connector 20b, a portion of a wiring pattern on the board 1 to the external connection cable 30 with ease. In particular, the configuration allows easy electrical connection of a portion of a wiring pattern on a thermally conductive substrate having high thermal conductivity or, more specifically, a metallic substrate having a coefficient of thermal conductivity of not less than 200 [W/m·K] to the external connection cable 30 (an outside conductor).

### Second Embodiment

FIG. 3(b) shows an electronic circuit board (a board 1) of a light-emitting device according to a second embodiment of the present invention. The board 1 shown in FIG. 3(b) is different from the board 1 of the first embodiment in that a wiring pattern 2b for connector loading is formed instead of the wiring pattern 2a for connector loading. As shown in FIG. 3(b), in the wiring pattern 2b for connector loading of the present embodiment, two land portions (first and second land portions) 2r are formed, one of the two land portions is used as a land portion for a first connector 20b, and the other is used as a land portion for a second connector 20s. Although the stability of a connection position of a connector at the time of reflowing is slightly lower than in the first embodiment, substantially the same effect as the working effect of the light-emitting device 10 described in the first embodiment is obtained while an area occupied by the wiring pattern 2a for connector loading with respect to the board 1 is smaller.

### Third Embodiment

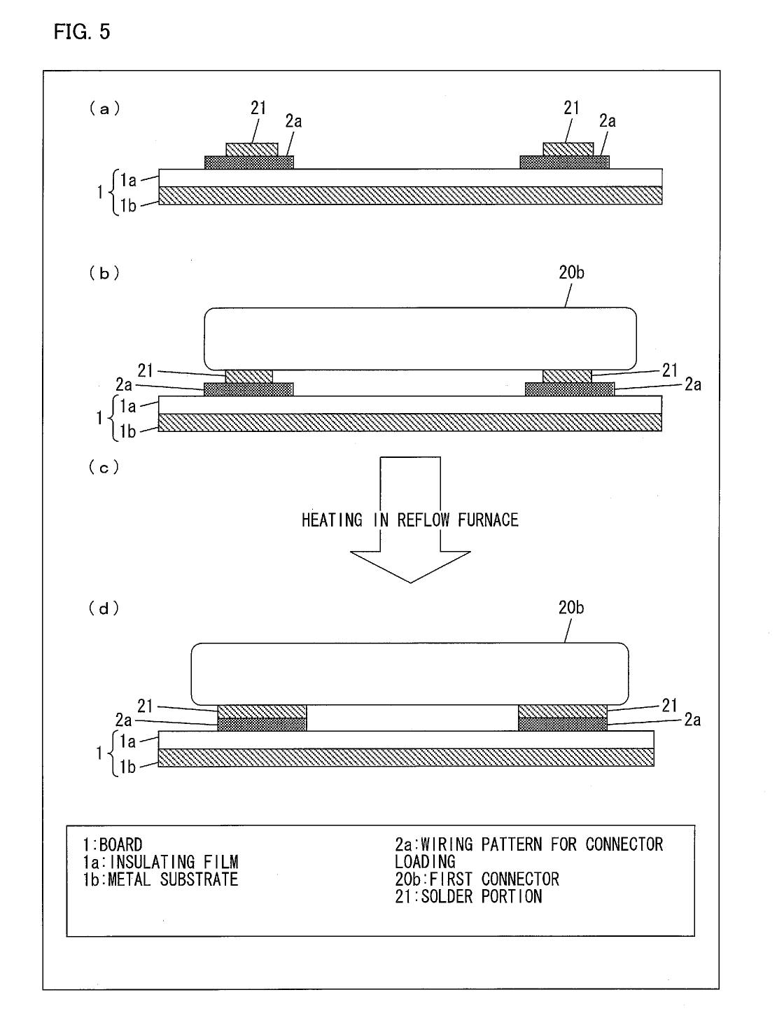

FIG. 5 is step views showing steps in a method for producing a light-emitting device according to a third embodiment of the present invention. Note that the light-emitting devices of the first and second embodiments can be both produced by the production steps of the present embodiment. Steps for producing the light-emitting device 10 of the first embodiment will be described below.

An insulating film 1a having a thickness of 100 μm is formed on one side of a metal substrate 1b made of aluminum by printing. More specifically, after printing a ceramic paint on the one side of the metal substrate 1b (to a thickness of 20 μm or more), the insulating film 1a is formed through a drying step and a sintering step. Note that a paint which exhibits electrical insulation, high thermal conductivity, and high light reflectivity after the sintering step is preferably used as the ceramic paint. As an example of the paint, a zirconia-based ceramic can be taken. The ceramic paint contains a consolidation agent for causing the ceramic paint to be deposited on the metal substrate 1b, a resin for facilitating printing, and a solvent for maintaining viscosity.

Wiring patterns, such as a wiring pattern 2a for connector loading, a wiring pattern 3 for wire connection, and a wiring pattern 4 for ZD loading, are formed on the insulating film 1a by screen printing.

Note that, in the present embodiment, Ag (silver) 1.0 μm in thickness, Ni (nickel) 2.0 μm in thickness, and Au (gold) 0.3 μm in thickness are formed as each of the wiring pattern 3 for wire connection and a wiring pattern 4b. Ag 1.0 μm in thickness, Cu (copper) 20 μm in thickness, Ni 2.0 μm in thickness, and Au 0.3 μm in thickness are formed as each of a first land portion 2f, a second land portion 2s, and a wiring pattern 4a.

The insulating film 1a may be made of a material having high thermal conductivity and high optical transparency, and wiring patterns, such as the wiring pattern 2a for connector loading, the wiring pattern 3 for wire connection, and the wiring pattern 4 for ZD loading, may be each made of a metal having a high optical reflectance. With this configuration, light leaking in a substrate surface direction from a light-emitting element 6 can be reflected by a wiring pattern (the wiring pattern 3 for wire connection not coated with a resin frame 7, in particular). Additionally, heat generated in the light-emitting element 6 can be dissipated from the insulating film 1a to the metal substrate 1b via a wiring pattern. This allows achievement of high thermal conductivity and high light reflectivity. As described above, a zirconia-based ceramic can be taken as an example of the material for the insulating film 1a. Silver can be taken as an example of the material for a wiring pattern.

A plurality of light-emitting elements 6 are fixed onto the insulating film 1a using resin paste. The light-emitting elements 6 are electrically connected by wires 5 for light-emitting element connection through wire bonding.

The resin frame 7 is formed on the insulating film 1a and wiring patterns, such as the wiring pattern 3 for wire connection and the wiring pattern 4 for ZD loading, so as to surround a region where the light-emitting elements 6 are arranged. A method for forming the resin frame 7 is not particularly limited, and a conventionally known method can be used.

After that, the region surrounded by the resin frame 7 is filled with resin, and a resin sealing layer 8 is formed to seal in the insulating film 1a in the region, the light-emitting elements 6, the wires 5 for light-emitting element connection, and the like.

Note that the reflectance of the insulating film 1a formed in the present embodiment (the reflectance for light having a wavelength of 450 nm) is higher by about 4% than that of the metal substrate 1b made of aluminum.

In the present embodiment, the thickness of the insulating film 1a is determined on the basis of the reflectance and dielectric strength. If the thickness of the insulating film 1a is too large, a crack may appear. On the other hand, if the thickness of the insulating film 1a is too small, a sufficient reflectance and sufficient dielectric strength may not be obtained. In order to secure the reflectance of a visible light region and insulation between the light-emitting elements 6 and the metal substrate 1b and prevent appearance of cracks, the thickness of the insulating film 1a to be formed on the metal substrate 1b is preferably not less than 20 μm and not more than 130 μm, more preferably not less than 50 μm and not more than 100 μm.

Reflowing will be described with reference to FIG. 5. As shown in FIG. 5(a), solder portions 21 are first placed (printed) on the wiring patterns 2a for connector loading by screen printing (a solder placement step).

As shown in FIG. 5(b), a first connector 20b is placed (mounted) on the solder portions 21.

As shown in FIG. 5(c), an electronic device 10 is heated in a reflow furnace (fusion bonding with the solder portions 21). After that, the heating by the reflow furnace is stopped, and the temperature of the electronic device 10 is sufficiently reduced [FIG. 5(d): a connector connection step].

In the above-described production method, the position of the first connector 20b relative to the first land portion 2f is likely to be stabilized during the heating in the reflow furnace in the connector connection step. For this reason, for example, at the time of electrical connection of the first land portion 2f to the first connector 20b with solder, a portion of a wiring pattern can be electrically connected to a connector just by heating the electronic device 10 in the reflow furnace while the solder portion 21 is placed on the first land portion 2f, and the first connector 20b is further placed on the solder portion 21 (hereinafter referred to reflowing). The stability of the position of the first connector 20b (or the connection position of a conductor portion of a connection cable 30) relative to a land portion is thus higher than that in conventional direct soldering of a conductor. Additionally, since the above-described reflowing is possible, the mounting time of the first connector 20b can be shortened. Moreover, as a result of the facilitation of production steps and the improvement in the stability of the position of the first connector 20b (or the connection position of the conductor portion of the connection cable 30) relative to the first land portion 2f, the electronic device 10 capable of supplying a large current more stably than ever can be produced.

### Fourth Embodiment

FIG. 6 shows a light-emitting device according to a fourth embodiment of the present invention and is a view showing a form in which the light-emitting device 10 according to the first embodiment is fixed on a heat sink 100 with fixing screws 9m.

The light-emitting device 10 has a threaded hole 9f for attaching the light-emitting device 10 to the heat sink 100 for each side of a hexagon as a board surface of a board 1. Note that although the number of threaded holes f of the present embodiment is six in total, the present invention is not limited to this, and the number may be one to five or seven or more, for example.

With this configuration, the light-emitting device 10 can be firmly attached to the heat sink 100 with the fixing screws 9m. The material for the fixing screw 9m is not particularly limited. In order to enhance heat dissipation to the heat sink 100, a material having high thermal conductivity is preferably used.

### [Recapitulation]

An electronic device (the light-emitting device 10) according to a first aspect of the present invention includes an electronic circuit board (the board 1) which includes a metallic substrate (the metal substrate 1b) and an insulating layer (1a) formed on the metallic substrate, an electronic circuit wiring pattern which is arranged on the insulating layer and is connected to an electron element (the light-emitting element 6), and a connector (the first connector 20b and/or the second connector 20s) which is loaded on the electronic circuit board and is configured to electrically connect the wiring pattern to an outside conductor (the connection cable 30).

In the above-described configuration, the electronic device has the connector loaded on the electronic circuit board. The connector is a connector for electrically connecting the electronic circuit wiring pattern to be connected to the electron element to the outside conductor.

For this reason, a user can electrically connect a portion of the wiring pattern of the electronic circuit board that is based on a metal substrate easy to process to a conductor with ease just by fitting the conductor into the connector loaded on the electronic circuit board without directly soldering the portion of the wiring pattern to the conductor. Accordingly, a user can electrically connect, via the connector, the portion of the wiring pattern on the board to an outside conductor with ease.

In an electronic device according to a second aspect of the present invention, at least one land portion for placing the connector may be formed at a portion of the wiring pattern, and the connector may be electrically connected to the land portion while the connector is placed on the land portion.

In the above-described configuration, the at least one land portion for placing the connector is formed at the portion of the wiring pattern, and the connector is electrically connected to the land portion while the connector is placed on the land portion. For this reason, a user can electrically connect the portion of the wiring pattern to the conductor with ease just by fitting the conductor into the connector without directly soldering the portion of the wiring pattern to the conductor. This eliminates the conventional need to fix a light-emitting device to a heat sink at the time of soldering and allows a user to electrically connect, via the connector, the portion of the wiring pattern on the board to an outside conductor with ease.

An electronic device according to a 13th aspect of the present invention is a method for producing an electronic device according to the second aspect and may include a solder placement step of placing solder on the land portion and a connector connection step of heating the electronic device in a reflow furnace while the connector is placed on a surface on a side opposite to a side with the land portion of the solder and electrically connecting the connector to the land portion through fusion bonding with the solder.

In the above-described method, a position of the connector relative to the land portion is likely to be stabilized during the heating in the reflow furnace in the connector connection step. For this reason, for example, at the time of electrical connection of the land portion to the connector with the solder, a portion of the wiring pattern can be electrically connected to the connector just by heating the electronic device in the reflow furnace while the solder is placed on the land portion, and the connector is further placed on the solder (hereinafter referred to as reflowing). The stability of the position of the connector (a connection position of a conductor) relative to the land portion is thus higher than that in conventional direct soldering of the conductor. Additionally, since the above-described reflowing is possible, the mounting time of the connector can be shortened. Moreover, as a result of the facilitation of production steps and the improvement in the stability of the position of the connector relative to the land portion, an electronic device capable of supplying a large current more stably than ever can be produced.

The above-described configurations or method allows easy electrical connection of a portion of a wiring pattern on a board to an outside conductor.

In an electronic device according to a third aspect of the present invention, in addition to the second aspect, the at least one land portion may comprise a plurality of land portions.

The above-described configuration improves the stability of the position (or the connection position of the conductor) relative to the land portion during the heating in the reflow furnace in the connector connection step of the production method according to the 13th aspect.

In an electronic device according to a fourth aspect of the present invention, in addition to the second aspect, the at least one land portion may comprise a plurality of land portions, and a first land portion for placing the first connector and a second land portion for placing the second connector may be formed as the plurality of land portions if the at least one connector includes two types of connectors which are a first connector large in size and a second connector smaller in size than the first connector.

The above-described configuration allows proper use of a plurality of connectors different in size.

In an electronic device according to a fifth aspect of the present invention, in addition to the first aspect, a land portion for a protection element may be formed at a portion of the wiring pattern, and the protection element may be electrically connected to the land portion while the protection element is placed on the land portion.

The above-described configuration allows the protection element to protect a light-emitting element from an electrostatic withstand voltage. As an example of such a protection element, a Zener diode can be taken.

In an electronic device according to a sixth aspect of the present invention, in addition to the first to fifth aspects, the metallic substrate may be made of an aluminum material. This allows the metallic substrate to have a coefficient of thermal conductivity of 230 [W/m·K]. Since aluminum is inexpensive, is easy to process, and is resistant to atmospheric humidity, the cost of producing electronic devices can be reduced. If the metallic substrate is made of aluminum having a low melting point, use of a zirconia-based ceramic which is sintered at a sintering temperature lower than the melting point of aluminum, as the material for the insulating layer, makes it possible to sinter ceramic onto a surface of the metallic substrate while maintaining a shape of the metallic substrate.

In an electronic device according to a seventh aspect of the present invention, in addition to the first to fifth aspects, the metallic substrate may be made of a copper material.

The above-described configuration allows the metallic substrate to have a coefficient of thermal conductivity of 398 [W/m·K].

In an electronic device according to an eighth aspect of the present invention, in addition to the first to seventh aspects, the insulating layer may be made of a zirconia-based ceramic material.

The above-described configuration has the effect of sintering ceramic on a surface of the metallic substrate while maintaining a shape of the metallic substrate, through use of a zirconia-based ceramic which is sintered at a sintering temperature lower than a melting point of a metal material, such as aluminum, which has a relatively high melting point (at a temperature higher at least than the sintering temperature of the zirconia-based ceramic) when the metal material is used as the material for the metallic substrate.

In an electronic device according to a ninth aspect of the present invention, in addition to the first to seventh aspects, the insulating layer may be made of a ceramic material having thermal conductivity and light reflectivity.

The above-described configuration allows dissipation of heat generated in a light-emitting element to the substrate via the insulating layer. Thus, high thermal conductivity can be achieved. Additionally, light leaking in a substrate surface direction from the light-emitting element can be reflected by the insulating layer. This allows achievement of high thermal conductivity and high light reflectivity. As an example of the material for the insulating layer described above, the zirconia-based ceramic described above can be taken.

In an electronic device according to a tenth aspect of the present invention, in addition to the first aspect, a light-emitting element as the electron element may be formed.

The above-described configuration allows improvement in luminous efficiency of the electronic device.

In an electronic device according to an 11th aspect of the present invention, in addition to the 11th aspect, the electronic device may include a bonding wire which connects the electron element to the wiring pattern.

Wire bonding is a technique low in cost and high in flexibility. For this reason, the above-described configuration allows a reduction in expense and processing cost.

In an electronic device according to a 12th aspect of the present invention, in addition to the second to fourth aspects, the connector and the land portion may be bonded with solder.

The above-described configuration allows reflowing of the connector and the land portion while the solder is placed on the land portion, and the connector is further placed on the solder in the connector connection step of the production method according to the 13th aspect.

### [Additional Matters]

The present invention is not limited to the above-described embodiments, and various changes may be made within the scope of the claims. An embodiment which is obtained by appropriately combining technical means disclosed in different ones of the embodiments is also included in the technical scope of the present invention. Additionally, a new technical feature can be formed by combining technical means disclosed in the embodiments.

### INDUSTRIAL APPLICABILITY

The present invention can be applied to an electronic circuit board on which an electronic circuit wiring pattern to be connected to an electron element is formed and an electronic device including the electronic circuit board.

### REFERENCE SIGNS LIST

1 board (electronic circuit board)
1 insulating film (insulating layer)
1b metal substrate (metallic substrate)
2a wiring pattern for connector loading
2f first land portion
2s second land portion
2r land portion (first land portion or second land portion)
4a wiring pattern (land portion for protection element)
5 wire for light-emitting element connection (bonding wire)
6 light-emitting element (electron element)
6a, 6b Zener diode (protection element)
10 light-emitting device (electronic device)
20b first connector
20s second connector
21 solder portion (solder)
30 connection cable (outside conductor)

1-13. (canceled)

14. An electronic device comprising:
an electronic circuit board which includes a metallic substrate and an insulating layer formed on the metallic substrate;
an electronic circuit wiring pattern which is arranged on the insulating layer and is connected to an electron element; and
a connector which is loaded on the electronic circuit board and is configured to electrically connect the wiring pattern to an outside conductor,
the wiring pattern including an anode wiring pattern and a cathode wiring pattern,
the electronic device having, as the connector, (i) an anode-side connector configured to electrically connect the anode wiring pattern to the outside conductor and (ii) a cathode-side connector configured to electrically connect the cathode wiring pattern to the outside conductor.

15. The electronic device according to claim 14, wherein at least one land portion for placing the connector is formed at a portion of the wiring pattern, and the connector is electrically connected to the land portion while the connector is placed on the land portion.

16. The electronic device according to claim 15, wherein the at least one land portion comprises a plurality of land portions.

17. The electronic device according to claim 15, wherein the at least one land portion comprises a plurality of land portions, and a first land portion for placing the first connector and a second land portion for placing the second connector are formed as the plurality of land portions if the at least one connector includes two types of connectors which are a first connector large in size and a second connector smaller in size than the first connector.

18. The electronic device according to claim 14, wherein a land portion for a protection element is formed at a portion of the wiring pattern, and the protection element is electrically connected to the land portion while the protection element is placed on the land portion.

19. The electronic device according to claim 14, wherein the metallic substrate is made of an aluminum material.

20. The electronic device according to claim 14, wherein the metallic substrate is made of a copper material.

21. The electronic device according to claim 14, wherein the insulating layer is made of a zirconia-based ceramic material.

22. The electronic device according to claim 14, wherein the insulating layer is made of a ceramic material having thermal conductivity and light reflectivity.

23. The electronic device according to claim 14, wherein a light-emitting element as the electron element is formed.

24. The electronic device according to claim 23, comprising:
a bonding wire which connects the electron element to the wiring pattern.

25. The electronic device according to claim 15, wherein the connector and the land portion are bonded with solder.

26. A method for producing an electronic device according to claim 15, comprising:
a solder placement step of placing solder on the land portion; and
a connector connection step of heating the electronic device in a reflow furnace while the connector is placed on a surface on a side opposite to a side with the land portion of the solder and electrically connecting the connector to the land portion through fusion bonding with the solder.
